(19) United States
(12) Patent Application Publication
(10) Pub. No.: US 2024/0275201 A1
(43) Pub. Date: Aug. 15, 2024

(54) Bidirectional Adaptive Terminal Voltage (BATV) with a Battery Pack

(71) Applicant: ZapBatt, Inc., Hermosa Beach, CA (US)

(72) Inventors: Charles Welch, Hermosa Beach, CA (US); David Felzer, Hermosa Beach, CA (US)

(73) Assignee: ZapBatt, Inc., Hermosa Beach, CA (US)

(21) Appl. No.: 18/570,485

(22) PCT Filed: Jun. 21, 2022
(86) PCT No.: PCT/US22/73066

§ 371 Date: Dec. 14, 2023

Related U.S. Application Data
(60) Provisional application No. 63/213,383, filed on Jun. 22, 2021.

(51) Int. Cl. H02J 7/04; H02J 7/00

(52) U.S. Cl. CPC H02J 7/04; H02J 7/0013; H02J 2207/20

(57) ABSTRACT

A Bidirectional Adaptive Terminal Voltage (BATV) system that enables a battery system to be integrated into various devices (or external loads), without having to modify the electrical characteristics of the devices. The battery system includes a battery cell stack and a battery management system electrically coupled with one another. The battery management system is further coupled with the BATV system, which is a bidirectional converter configured to operate in either a buck or boost mode, depending on the voltage conditions of an external load when power is required to be delivered from the battery system to the external load. When the battery system is being recharged from an external power supply or from regenerative energy absorption, the BATV system also operates in either buck or boost mode, as required by recharging conditions.

### BACKGROUND OF THE INVENTION

### Technical Field

The present invention relates generally to battery systems. More particularly, the present invention relates to a Bidirectional Adaptive Terminal Voltage (BATV) system performing bidirectional DC to DC voltage and power regulation for use with managing the charge and discharge of a connected battery pack.

### Background Art

Rechargeable batteries are widely used as energy storage devices in a variety of different applications; they have relatively high energy and power density and relatively low cost when compared to other energy storage technologies. Among available rechargeable battery types, the lithium-ion battery is highly favored and widely used due to its high power and energy density. The rechargeable batteries are integrated into portable electronics, consumer products, light electric vehicles, hybrid and electric vehicles, renewable power systems, and numerous other devices/systems.

However, integration of a rechargeable battery into different types of devices may be limited by the specifications of the power consuming portion of the device, including such common devices as motors, display screens, or other electronic devices requiring battery power. For instance, it is difficult integrate a rechargeable battery into battery powered devices designed for an input voltage range different from the rechargeable battery's true nominal voltage or voltage range. Additionally, for devices that also send power back to the battery system, the voltage delivered to the rechargeable battery pack must be kept within a certain range for the batteries to be safely charged, and therefore the system requires conditioning of the power and voltage delivered to the battery pack.

Accordingly, there remains a need for a system that allows seamless integration of a rechargeable battery into different devices for various applications without the requirement of ensuring that the devices required voltages match up with the voltage range of the battery pack desired for use.

### DISCLOSURE OF INVENTION

To solve the foregoing problem, the present invention provides a Bidirectional Adaptive Terminal Voltage system (“BATV” herein). The BATV system enables integration of a rechargeable battery system into various devices (or connection to external loads) without having to modify the electrical characteristics of the devices into which they are integrated. The battery system includes a battery cell stack, which may contain one or more cells connected in series and/or parallel, and also includes a battery management system electrically coupled to the battery cell stack. The BATV combines electronic hardware and software that performs conversion, regulation, control, and communication functions.

In addition, the BATV system is a bidirectional converter, also variously referred to as a DC-DC, or buck/boost converter. The BATV system may regulate a current flowing between high voltage and low voltage ports in a direction designated by a direction control signal (DIR), and it may regulate a voltage across output terminals of the BATV system. Current levels and voltage regulation levels are programmed through a combination of analog and digital signals. Through the combination of analog and digital signals, the system is able to rapidly switch back and forth within milliseconds between power flowing from a low voltage port to a high voltage port and a high voltage port to a low voltage port, based on DIR inputs that dictate the device's circumstantial needs.

Further, the BATV system may be electrically coupled to the battery system to form a battery pack. An external load may be connected to the battery pack via a positive terminal and a negative terminal of the battery pack going through the BATV system.

In an embodiment, when power is required to be delivered from the battery system to an external load, the BATV system operates in either a buck or boost mode, depending upon the voltage requirements of the external load and the current terminal voltage of the battery pack. Subsequently, when the battery system is being recharged from the external power supply or from regenerative energy absorption, the BATV system also operates in either a buck (step-down) or a boost (step-up) mode, as required by the recharging conditions. To that end, input and output voltage ranges and current flow may be programmable to enable the battery system to be used in applications requiring a variety of voltage and current specifications. Examples of various applications include different cell count battery stacks for the same or different output voltages, as well as different load or charge voltage and current characteristics for the same or different battery cell stacks.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The embodiments disclosed herein will be further explained with reference to the attached drawings, which are not scaled. Due emphasis is therefore placed on the principles of operation of the disclosed embodiments, of which:

FIG. 1 is a schematic diagram of a battery cell according to some embodiments;

FIG. 2 is a schematic diagram of a battery cell stack comprising multiple battery cells, according to some embodiments;

FIG. 3A is a block diagram of a battery management system, also according to some embodiments;

FIG. 3B is a schematic of battery cell stack safety switches incorporated in the battery management system of FIG. 3A;

FIG. 4 is a block diagram of a battery system.

FIG. 5 is a block diagram of the battery system of FIG. 4 connected with an external load;

FIG. 6 is a block diagram of a Bidirectional Adaptive Terminal Voltage (BATV) system according to some embodiments;

FIG. 7 is a block of diagram of a battery pack; and

FIG. 8 is a block diagram of the battery pack connected with the external load.

### BEST MODE FOR CARRYING OUT THE INVENTION

In the following description details are set forth to provide a thorough understanding of the present invention. It will be apparent to one skilled in the art that the present invention may be practiced without at least some of the specificity provided in these details. In other instances, apparatuses and methods are shown in a generalized form, i.e., a block diagram form, to facilitate the fundamental inventive concepts and principles of operation without needlessly complicating the present disclosure.

Reference in this specification to “one embodiment” or “an embodiment” means that a particular feature, structure, or characteristic described in connection with the embodiment is included in at least one embodiment of the present disclosure. The phrase “in one embodiment” in various places in the specification signifies that the feature or characteristic is not necessarily present in all embodiments, nor are separate or alternative embodiments mutually exclusive of other embodiments. Further, the terms “a” and “an” herein do not denote a limitation of quantity, but rather denote the presence of at least one of the referenced items or limitations. Moreover, various features are described that may be present in some embodiments while not in others. Similarly, various requirements are described that may be requirements for some embodiments but not for others.

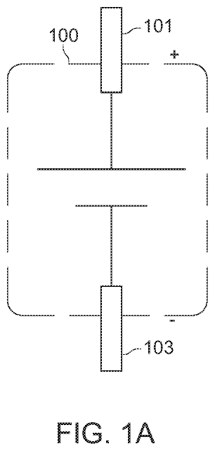

Referring first to FIG. 1A, there is shown a schematic diagram of a battery cell 100 according to some embodiments. The battery cell 100 may be a rechargeable cell. For example, battery cell 100 may be a nickel-cadmium (NiCd) battery, a nickel-metal hydride (NiMH) battery, a lithium-ion (Li-ion) battery, a lithium-ion polymer (LiPo) battery, a lithium titanate (LTO) battery, or the like. The battery cell 100 includes two terminals, namely, a positive terminal 101 and a negative terminal 103. The battery cell 100 may be connected to other battery cells or any electronic device through the positive terminal 101 and the negative terminal 103. Specifications of the battery cell 100 are selected based on user requirements.

In an embodiment, the battery cell 100 of following specifications may be used: 1.5 V˜2.7 V, 2.3 V nominal, 23 Ah, 52 Wh, 106×116×22 mm, (6.17×6.57×0.87 in), 550 g (19.6 oz, 1.21 lbs), 96 Wh/kg, 202 Wh/L, −30˜55° C. operating, 115 A charge/discharge (continuous), 200 A Max (<10 seconds).

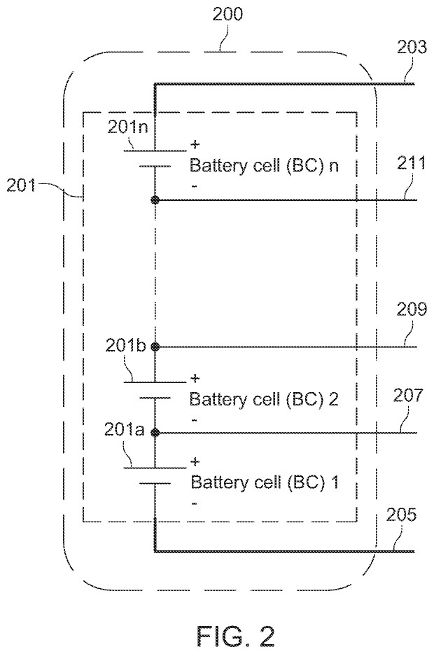

According to an embodiment, multiple battery cells are used to form a battery cell stack. For instance, the multiple battery cells may be connected end-to-end to form the battery cell stack as described below and with reference to FIG. 2.

FIG. 2 is a schematic diagram of a battery cell stack 200 made up of multiple battery cells 201a-201n, according to some embodiments. The multiple battery cells 201a-201n are connected end-to-end in series, i.e., a positive terminal of the battery cell 201a cell is connected to a negative terminal of the battery cell 201b, and then again a positive terminal of the battery cell 201b cell is connected to a negative terminal of another battery cell, and so on, to form the battery cell stack 200. In some alternate embodiments, the multiple battery cells 201a-201n may be connected in parallel. The battery cell stack 200 includes two terminals, namely, a positive terminal 203 and a negative terminal 205. The battery cell stack 200 may be connected to any external electronic device through the positive terminal 203 and the negative terminal 205. Additionally, in some embodiments, a terminal is associated with each battery cell of the multiple battery cells 201a-201n. For example, terminals 207, 209, and 211 are associated with the battery cells 201a, 201b, and 201n, respectively.

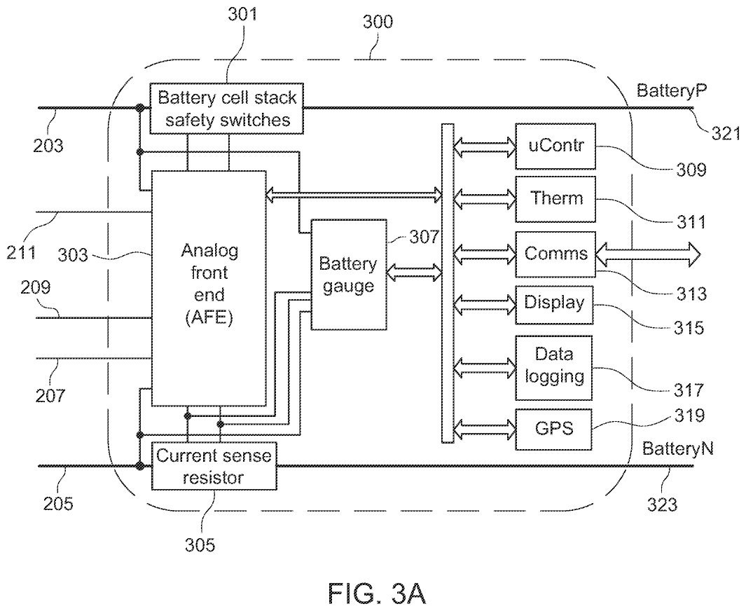

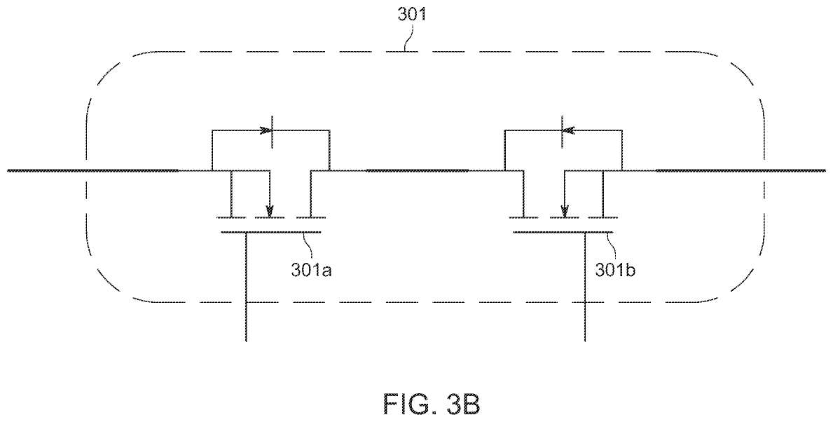

Further, the battery cell stack 200 may be connected to a battery management system, as described below and with reference first to FIG. 3A.

FIG. 3A is a block diagram of a battery management system 300, according to some embodiments of the present invention. The battery management system (or BMS) 300 is coupled to the battery cell stack and is used for control, safety, and information monitoring of the battery cell stack 200. Combined, the battery cell stack and the battery management system are referred to herein as a battery system. The battery management system 300 includes battery cell stack safety switches 301, which facilitate connection and disconnection of the battery cell stack from the load or charger to ensure safe use and to control current flow, an analog front end (AFE) 303, which monitors the voltage of the battery cell stack and current flowing into and out of the battery cell stack to control the safety and performance of the battery cell stack, a current sense resistor 305 to sense the current flowing into and out of the battery cell stack, and a battery gauge 307 to determine and report the state of health of the battery cell stack, communications for internal and external signals, and so forth.

Additionally, the battery management system (BMS) 300 includes a microcontroller 309 for battery system management, a thermal management component 311 for monitoring the temperature of the battery cells and other components in the BMS, a communications component 313 for communicating battery control and status to and from devices outside the battery system, a display component 315 to display battery system status, a data logging component 317 to store data regarding the status and behavior of the battery system, and a GPS component 319 to identify the time and the location of the battery system. The thermal management component 311 is a discrete digital temperature sensor for thermal monitoring and sends signals to the microcontroller. It enables the ability to reduce the maximum available charge or discharge power going through the system in the event that certain predetermined temperature thresholds are reached, and thereby to protect the onboard electronics from overheating. The system preferably includes at least one pulse width modular (PWM) controlled fan for cooling high heat generating components on the PCBA, such as the FETs and inductors or other magnetics in the system that require specific operating temperature ranges to maintain peak power output. Fan operation and speed is dictated by the microcontroller, which is programed to base fan speed decisions on predetermined temperature thresholds and readings from the thermal sensor(s). The microcontroller is programmed such that prior to limiting available power in and out of the battery pack, the microcontroller communicates to the PWM cooling fan to increase its speed to increase airflow circulation over the components generating heat in the system and thereby to allow the system to continue to operate at its full potential.

The battery management system 300 further includes a positive terminal 321 and a negative terminal 323 through which the battery management system 300 can be connected to other components or systems, including external components and systems.

FIG. 3B is a schematic diagram of battery cell stack safety switches 301 incorporated in the battery management system of FIG. 3A. Battery cell stack safety switches 301 comprise a first switch 301a and a second switch 301b. The combination of the first and second switches allows passing current into or blocking of current from the battery cell stack. This represents one possible implementation of the switch function. The switch function may also be implemented in other circuit device structures and combinations and in such implementations may require different numbers of components.

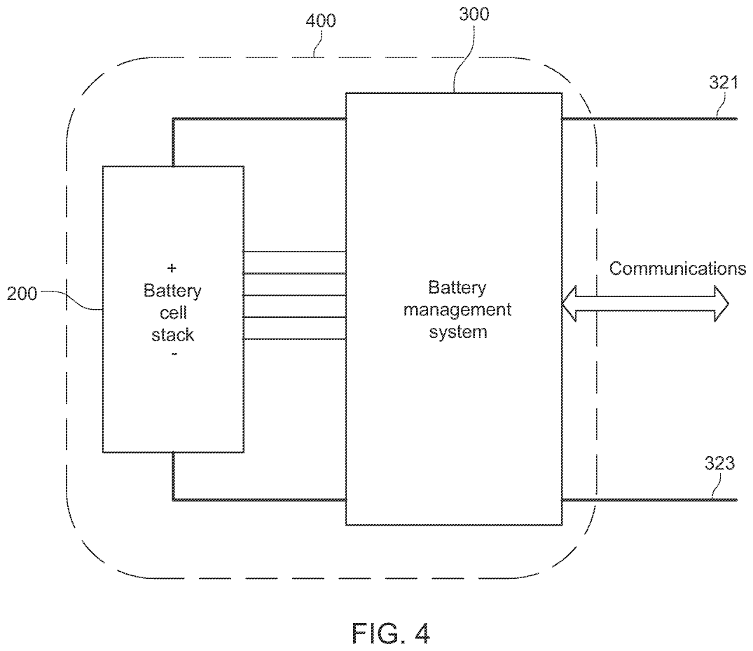

FIG. 4 is a block diagram of a battery system 400 according to various embodiments. The battery cell stack 200 and the battery management system 300 electrically coupled to one another are collectively characterized as the battery system 400. The positive terminal 321 and the negative terminal 323, respectively, may act as a positive terminal and a negative terminal of the battery system 400. The battery system 400 may be connected to an external load and may supply electrical energy to the external load. The battery system 400 may also be connected to an external charger and may thus be charged by the external charger.

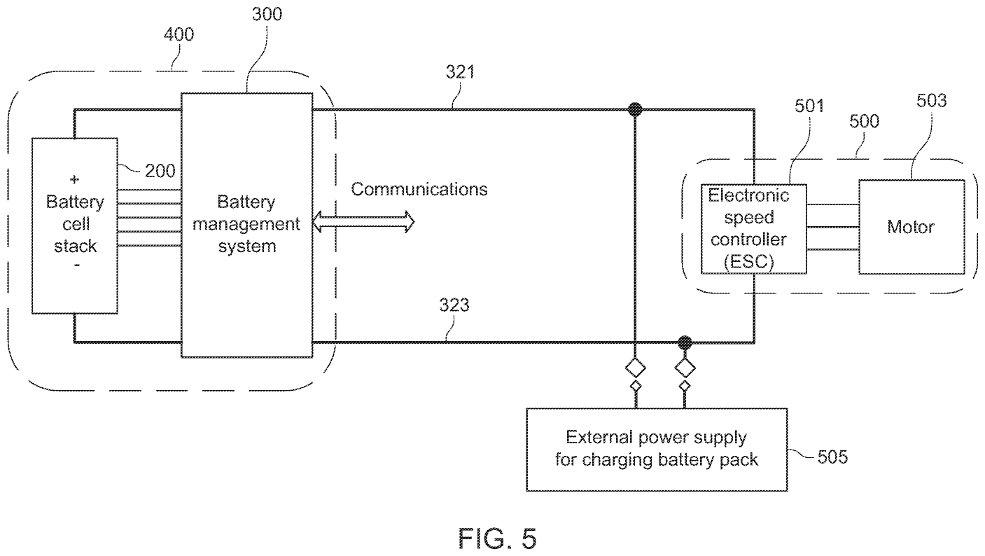

FIG. 5 is a block diagram of the battery system 400 connected to an external load 500, according to some embodiments. In an embodiment, the external load 500 may include an electronic speed controller 501 and a variable speed motor 503. The electronic speed controller 501 is configured to control a speed of the motor 503. The battery system 400 may discharge the electrical energy across the external load 500 to operate the external load 500. In some embodiments, the battery system 400 may be charged using an external power supply 505, which in embodiments may be a direct current (DC) source.

Different types of external loads within which the battery system 400 may be integrated are limited by the specification of the battery cell stack 200. For instance, it is difficult integrate the battery system 400 with battery powered devices designed for an input voltage range which is different than the battery cell stack's 200 true nominal voltage or voltage range.

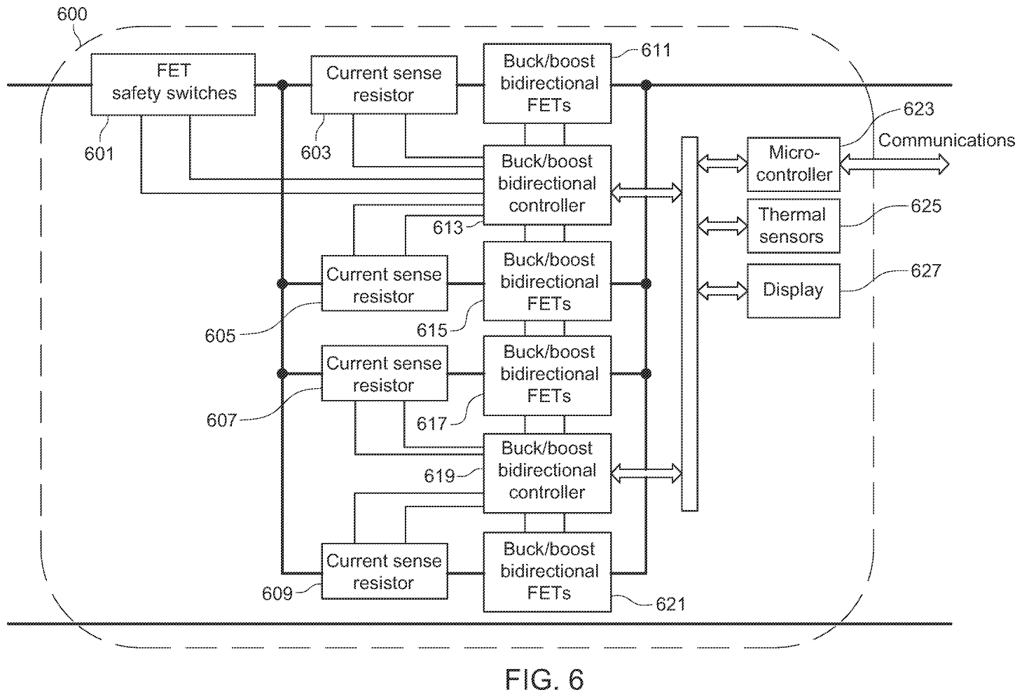

To address this limitation a Bidirectional Adaptive Terminal Voltage (BATV) system is provided. FIG. 6 is a block diagram of such a BATV system 600. The BATV system 600 allows the battery system 400 to be integrated into various devices (or external loads), without modifying the electrical characteristics of the devices into which they are integrated. The BATV system 600 is a combination of electronic hardware and software that performs conversion, configuration, control, and communication functions. In addition, the BATV system 600 is a bidirectional converter, sometimes referred to as either a DC-DC or a buck/boost converter. The BATV system 600 may regulate a current flowing between high voltage and low voltage ports in a direction designated by a direction control signal (DIR) and may regulate a voltage across output terminals of the BATV system 600. Current and voltage regulation levels are programmed through analog or digital signals flowing in the BATV system 600. The BATV system 600 comprises FET safety switches 601 that enable connection and disconnection of the battery from the load or charger for safety or for control of current flow. A current sense resistor 603 senses the current flowing into and out of the battery pack, and a buck/boost bidirectional FET assembly 611 (to switch current in the buck-boost function) is connected to a buck-boost bidirectional controller 613 to control the operation of the buck-boost conversion. The combination of the current sense resistor 603, buck-boost bidirectional FET assembly 611, and buck-boost bidirectional controller 613 may be constructed in either a single phase or multiphase implementation. The BATV system 600 further comprises a microcontroller 623 for BATV system management, thermal sensor(s) 625 for monitoring the temperature of components in the BATV, and a display 627 to display BATV and battery system status. Note that in this view, there are four sets of buck-boost FETs shown with two buck-boost controller blocks. In other embodiments, a controller may be provided for every FET pair.

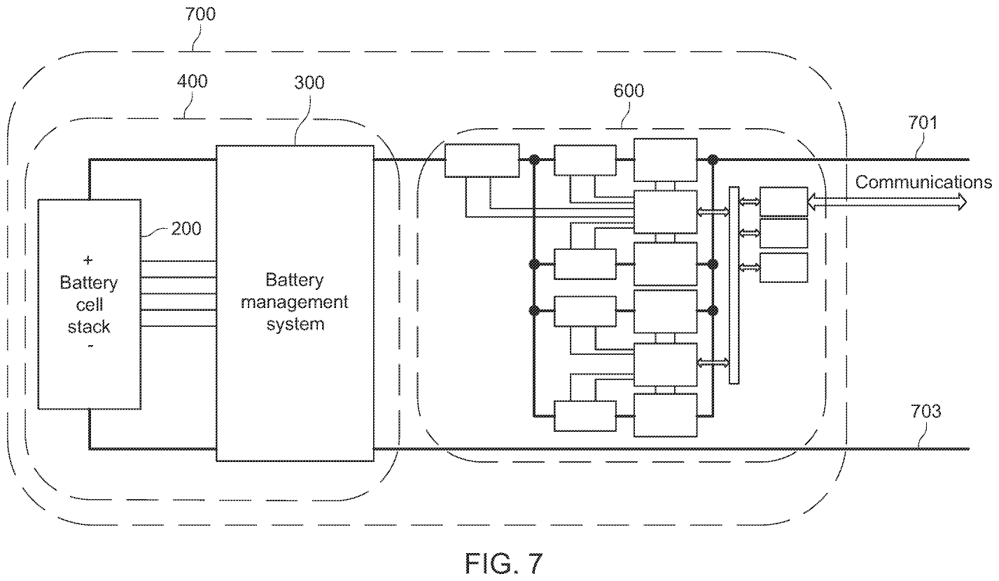

The BATV system 600 may be electrically coupled to the battery system 400 to form a battery pack, as described now with reference to FIG. 7, which is a block of diagram of a battery pack 700, according to some embodiments. A combination of the battery system 400 and the BATV system 600 electrically coupled with one another is referred to as the battery pack 700. The battery pack 700 may be connected to the external load 500 via a positive terminal 701 and a negative terminal 703. Input and output voltage ranges and the current flow may be programmable to enable the battery system 400 to be used in applications where a variety of voltage and current specifications are required. Some examples of various applications are different cell battery stacks for the same or different output voltages, and different load or charge current characteristics for the same or different battery cell stacks.

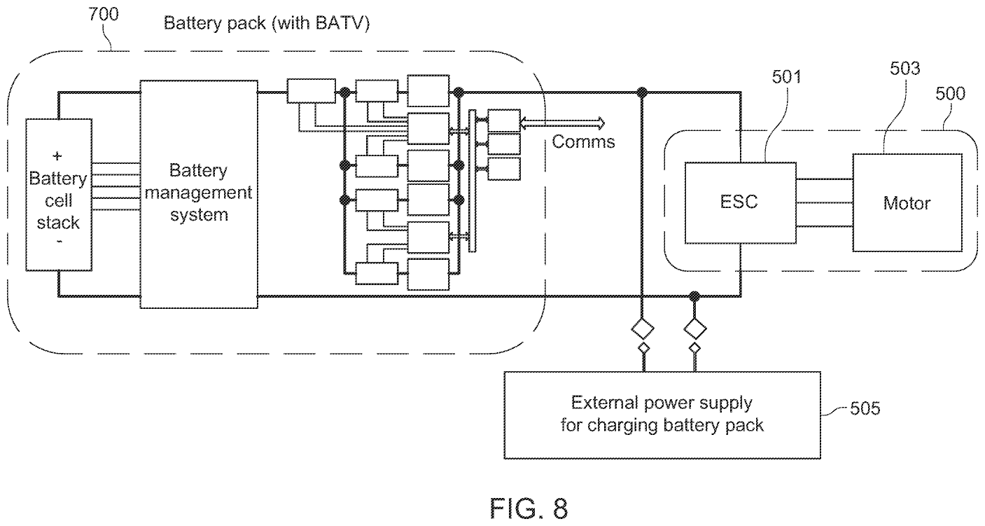

FIG. 8 is a block diagram of an exemplary application of the battery pack 700, according to some embodiments. The battery pack 700 is connected to an external load 500. When power is delivered from the battery system 400 to the external load 500, the BATV system 600 operates in either a buck or boost mode, depending upon the voltage conditions of the external load 500. Subsequently, when the battery system 400 is being recharged from the external power supply 505 or from regenerative energy absorption, the BATV system 600 also operates in either buck or boost mode, as required by recharging conditions. To that end, the BATV system 600 enables the battery system 400 to be used for different applications involving different load voltages and currents. Further, the BATV system 600 allows the battery system 400 to be recharged from different external power supplies.

The foregoing description provides exemplary embodiments only, and is not intended to limit the scope, applicability, or configuration of the disclosure. Rather, the disclosure herein of the exemplary embodiments will provide those skilled in the art with an enabling description for implementing one or more exemplary embodiments. Contemplated as encompassed within the scope of the claims are various changes that may be made in the function and arrangement of elements without departing from the spirit and scope of the subject matter disclosed, which is set forth in the appended claims.

What is claimed as invention is:

1. A rechargeable battery pack, comprising:
a battery system including a battery cell stack coupled to a battery management system (BMS); and
a bidirectional adaptive terminal voltage system (BATV) coupled to said battery system, said BATV combining electronic hardware and software configured with a negative terminal and a positive terminal for coupling the rechargeable battery pack to a battery charger, to an external load, or to enable its integration into an electronic device without modifying the electrical characteristics of the devices into which it is integrated.

2. The rechargeable battery pack of claim 1, wherein said BMS comprises:
one or more battery cell stack safety switches to facilitate connection and disconnection of the battery cell stack from the load or charger and to ensure safe use and to control current flow;
an analog front end that monitors the voltage of the battery cell stack and current flowing into and out of the battery cell stack to control the safety and performance of the battery cell stack;
a current sense resistor to sense the current flowing into and out of the battery system; and
a battery gauge to determine and report an accurate current state of charge, state of health of the battery system and for communications for internal and external signals.

3. The rechargeable battery pack of claim 2, wherein said BMS further comprises:
a microcontroller for battery system management, including the management of communications between said BMS and said BATV required to synchronize the functionality and operation of said BMS and said BATV;
a network of thermal management components to monitor the temperature of the battery cells and other components on the BMS printed circuit board assembly (PCBA);
a communications component for communicating battery control and status to and from devices outside the battery pack;
a display to show battery system status;
a positive terminal and a negative terminal through which said BMS can be connected to other components or systems.

4. The rechargeable battery pack of claim 3, further including a data log to store data regarding the status and behavior of the battery system.

5. The rechargeable battery pack of claim 3, further including a GPS component to identify the time and the location of the battery pack.

6. The rechargeable battery pack of claim 3, wherein said thermal management components comprises a network of digital temperature sensors configured to send signals to said microcontroller, and said microcontroller is programmed to reduce the maximum available charge or discharge power going through said battery system in the event that certain predetermined temperature thresholds are reached.

7. The rechargeable battery pack of claim 1, wherein said BATV is a bidirectional buck-boost converter that performs conversion, voltage regulation, control, and communication functions and is configured to regulate power flowing between high voltage and low voltage ports in a direction designated by a direction control signal and to regulate a voltage across output terminals of said BATV. In some instances the voltage being supplied externally to the high voltage port is fluctuating or is supplied at a fixed voltage, and the BATV is regulating to a specific fixed voltage to be delivered to the low voltage port; in some instances the voltage supplied externally to the high voltage port is fluctuating or is supplied at a fixed voltage and the BATV is regulating to fixed current and fluctuating voltage to be delivered to the low voltage port; in some instances the voltage on the low voltage port is fluctuating and the BATV is regulating to a specific voltage to be delivered to the high voltage port for external use.

8. The rechargeable battery system of claim 7, wherein said BATV comprises:
FET safety switches configured to enable connection and disconnection of the rechargeable battery system from a load or a battery charger and for safe control of current flow;
a current sense resistor that senses current flowing into and out of said battery pack;
a buck-boost bidirectional FET assembly to switch current in the buck-boost function;
a buck-boost bidirectional controller connected to said FET assembly to control the operation of the buck-boost conversion;
wherein said current sense resistor, buck-boost bidirectional FET assembly, and said buck-boost bidirectional controller are configured in combination in either a single phase or multiphase implementation.

9. The rechargeable battery system of claim 8, wherein said BATV system further comprises;
a microcontroller for BATV system management; and
at least one thermal sensor for monitoring the temperature of components in said BATV;
a display to display BATV and/or battery system status.

10. The rechargeable battery pack of claim 1, wherein when power is required to be delivered from said battery pack system to an external load, said BATV system operates in either a buck mode or a boost mode depending on the voltage requirements of the external load and the current terminal voltage of the battery pack.

11. The rechargeable battery system of claim 10, wherein when said rechargeable battery pack is being recharged from an external power supply or from regenerative energy absorption, said BATV system operates in either a buck or boost mode as required by recharging conditions.

12. The rechargeable battery system of claim 11, wherein said BATV is programmable to enable input and output voltage ranges and current flow suitable for a variety of voltage and current specifications.

13. A battery charging system, comprising:
a rechargeable battery cell stack;
a battery management system coupled to said battery cell stack; and
a bidirectional adaptive terminal voltage system coupled to said battery management system and configured for connection to a battery charger, to an external load, or for integration into an electronic device.

14. The battery charging system of claim 13, wherein said battery management system is configured with hardware and software to monitor voltage of the battery cell stack and current flowing into and out of the battery cell stack, to sense the current flowing into and out of the battery system, to determine and report an accurate current state of charge, state of health of the battery system, to manage communications between said battery management system and said bidirectional adaptive terminal voltage system.

15. The battery charging system of claim 14, wherein said bidirectional adaptive terminal voltage system is a bidirectional buck-boost converter configured to regulate power flowing between high voltage and low voltage ports in a direction designated by a direction control signal and to regulate a voltage across output terminals of said bidirectional adaptive terminal voltage system.

16. The battery charging system of claim 15, wherein said bidirectional adaptive terminal voltage system is programmable to enable input and output voltage ranges and current flow suitable for a variety of voltage and current specifications.
